(19) United States
(12) Patent Application Publication
(10) Pub. No.: US 2025/0275394 A1
(43) Pub. Date: Aug. 28, 2025

(54) Display Apparatus

(71) Applicant: LG Display Co., Ltd., Seoul (KR)

(72) Inventors: Byung-Jun Lim, Paju-si (KR); Hwa-Jun Jung, Paju-si (KR)

(21) Appl. No.: 18/954,134

(22) Filed: Nov. 20, 2024

(30) Foreign Application Priority Data
Feb. 26, 2024 (KR) 10-2024-0027302

(51) Int. Cl. H10K 59/131

(52) U.S. Cl. CPC H10K 59/131

(57) ABSTRACT

A display apparatus includes: a display panel with a display region including first to fifth regions and including pixels; a data wiring; a horizontal link wiring connected to the data wiring in the third region at a third contact hole along a sloped boundary between the first and third regions; a vertical link wiring connected to the horizontal link wiring at a first contact hole along a sloped boundary between the first and second regions; a horizontal power wiring and a vertical power wiring transmitting a low-potential driving voltage, wherein a second contact hole is formed in the fifth region to connect the horizontal power wiring and the vertical power wiring, and is arranged in a sloped array form or a vertical array form in the fifth region.

### CROSS REFERENCE TO RELATED APPLICATION

The present application claims the priority to and benefit of Republic of Korea Patent Application No. 10-2024-0027302 filed on Feb. 26, 2024, which is hereby incorporated by reference in its entirety.

### FIELD OF TECHNOLOGY

The present disclosure relates to a display apparatus.

### DISCUSSION OF THE RELATED ART

As the information society develops, demand for display apparatuses for displaying images is increasing in various forms, and recently, various flat display apparatuses such as organic light emitting display apparatuses and liquid crystal display apparatuses are being utilized.

Here, the organic light emitting display apparatus is widely used because it has advantage of being small, lightweight, thin, and operating at low power.

### SUMMARY

An advantage of the present disclosure is to provide a display apparatus that can improve an appearance defect in which a boundary is visible between a region where horizontal link wirings and vertical link wirings are arranged and a region where high-density voltage contact holes are formed around the region of the horizontal link wirings and vertical link wirings.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display apparatus includes: a display panel in which a display region is defined and which includes pixels arranged along a plurality of vertical lines and horizontal lines, the display region including a first region, second and third regions respectively located on inner and outer sides, in a horizontal direction, of the first region, and a fifth region located on an upper side, in a vertical direction, of the first region; a data wiring extending along the vertical line of the display region; a horizontal link wiring extending along the horizontal line of the first region, and connected to the data wiring arranged in the third region at a third contact hole that is arranged along a sloped boundary between the first and third regions; a vertical link wiring extending along the vertical line of the second region, and connected to the horizontal link wiring at a first contact hole that is arranged along a sloped boundary between the first and second regions; a horizontal power wiring extending along the horizontal line of the second, third, and fifth regions and transmitting a low-potential driving voltage; and a vertical power wiring extending along the vertical line of the first, third, and fifth regions and transmitting the low-potential driving voltage, wherein a second contact hole is formed in the fifth region to connect the horizontal power wiring and the vertical power wiring, and wherein the second contact hole is arranged in a sloped array form or a vertical array form in the fifth region.

In another embodiment, a display apparatus includes: a display panel in which a display region is defined and which includes pixels arranged along a plurality of vertical lines and horizontal lines, the display region including a first region, a second region located on an inner side, in a horizontal direction, of the first region, and a fifth region located on an upper side, in a vertical direction, of the first region; a data wiring extending along the vertical line of the display region; a horizontal link wiring extending along the horizontal line of the first region; a vertical link wiring extending along the vertical line of the second region, and connected to the horizontal link wiring at a first contact hole that is arranged along a boundary between the first and second regions; and a horizontal power wiring and a vertical power wiring respectively extending along the horizontal line and the vertical line of the fifth region, and transmitting a low-potential driving voltage, wherein a second contact hole connecting the horizontal power wiring and the vertical power wiring in the fifth region is arranged in a sloped array form or a vertical array form.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view schematically illustrating a display apparatus according to a first exemplary embodiment of the present disclosure;

FIG. 2 is a circuit diagram schematically illustrating an example of a pixel according to a first exemplary embodiment of the present disclosure;

FIG. 3 is a block diagram schematically illustrating a configuration of a gate driving portion of a display apparatus according to a first exemplary embodiment of the present disclosure;

FIG. 4 is a view schematically illustrating arrangements of link wirings and power wirings formed in a display panel according to a first exemplary embodiment of the present disclosure;

FIG. 5 is a view schematically illustrating an arrangement of data wirings formed in a display panel according to a first exemplary embodiment of the present disclosure;

FIG. 6 is a view schematically illustrating a connection structure of link wirings and data wirings according to a first exemplary embodiment of the present disclosure;

FIG. 7 is a view enlarging a region R1 of FIG. 4 according to an embodiment of the present disclosure;

FIG. 8 is a cross-sectional view taken along a line I-I′ of FIG. 7 according to an embodiment of the present disclosure;

FIG. 9 is a view enlarging a region R2 of FIG. 4 according to an embodiment of the present disclosure;

FIG. 10 is a cross-sectional view taken along a line II-II′ of FIG. 9 according to an embodiment of the present disclosure;

FIG. 11 is a view enlarging a region R3 of FIG. 4 according to an embodiment of the present disclosure;

FIG. 12 is a cross-sectional view taken along a line III-III′ of FIG. 11 according to an embodiment of the present disclosure;

FIG. 13 is a view enlarging a region R4 of FIG. 4 according to an embodiment of the present disclosure;

FIG. 14 is a cross-sectional view taken along a line IV-IV′ of FIG. 13 according to an embodiment of the present disclosure;

FIG. 15 is a view schematically illustrating arrangements of link wirings and power wirings formed in a display panel according to a second exemplary embodiment of the present disclosure;

FIG. 16 is a view schematically illustrating arrangements of link wirings and power wirings formed in a display panel according to a third exemplary embodiment of the present disclosure; and

FIG. 17 is a view schematically illustrating arrangements of link wirings and power wirings formed in a display panel according to a fourth embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure, and the present disclosure may be defined by the scope of the claims.

The shapes, sizes, dimensions (e.g., length, width, height, thickness, radius, diameter, area, etc.), ratios, angles, number of elements, proportions, angles, numbers, and the like disclosed in the drawings for explaining the embodiments of the present disclosure are illustrative, and the present disclosure is not limited to the illustrated matters. The same reference numerals refer to the same components throughout the description.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Furthermore, in describing the present disclosure, if it is determined that a detailed description of the related known technology unnecessarily obscure the subject matter of the present disclosure, the detailed description thereof can be omitted. When ‘comprising’, ‘including’, and ‘having’ and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

In the case of a description of a temporal relationship, for example, when a temporal precedence is described as ‘after’, ‘following’, ‘before’, and the like, cases that are not continuous can be included unless ‘directly’ or ‘immediately’ is used.

In describing components of the present disclosure, terms such as first, second “A,” “B,” “(a),” and “(b)” and the like can be used. These terms are only for distinguishing the components from other components, and an essence, order, order, or number of the components is not limited by the terms.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Respective features of various embodiments of the present disclosure can be partially or wholly connected to or combined with each other and can be technically interlocked and driven variously, and respective embodiments can be independently implemented from each other or can be implemented together with a related relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, exemplary embodiments of the present disclosure are described in detail with reference to the drawings. Meanwhile, in the following embodiments, the same and like reference numerals are assigned to the same and like components, and detailed descriptions thereof may be omitted.

### First Exemplary Embodiment

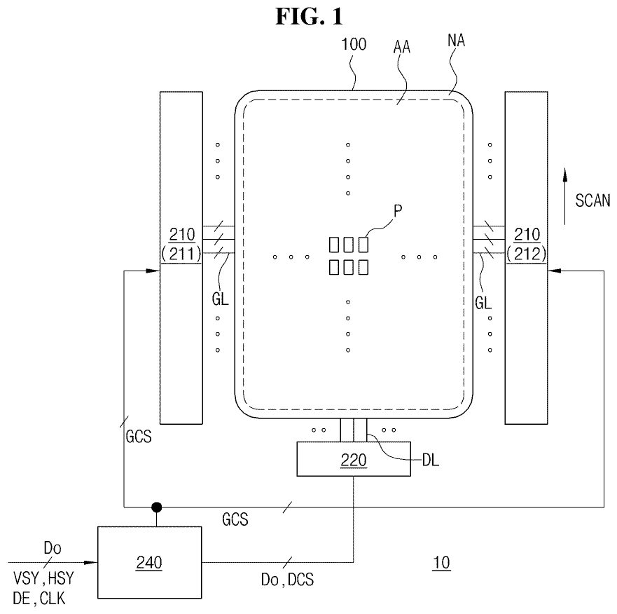

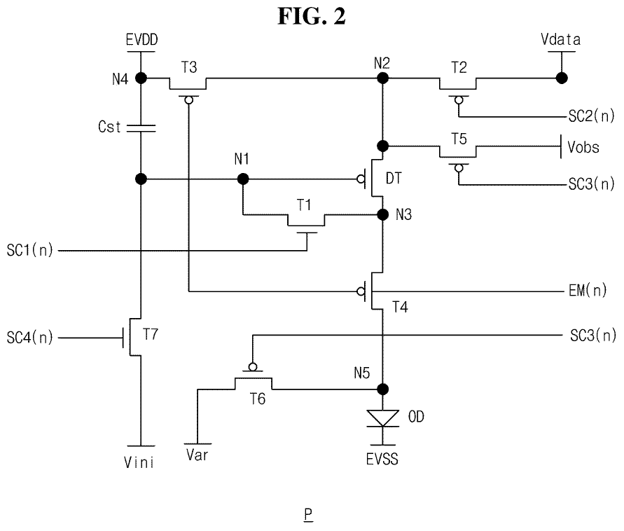

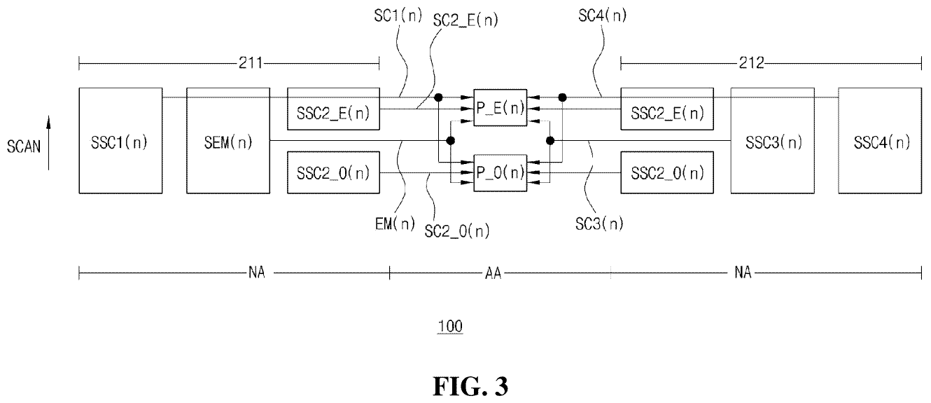

FIG. 1 is a view schematically illustrating a display apparatus according to a first exemplary embodiment of the present disclosure. FIG. 2 is a circuit diagram schematically illustrating an example of a pixel according to a first exemplary embodiment of the present disclosure. FIG. 3 is a block diagram schematically illustrating a configuration of a gate driving portion of a display apparatus according to a first exemplary embodiment of the present disclosure.

Prior to a specific description, the display apparatus 10 according to the present exemplary embodiment can be one of all types of display apparatuses, including a light emitting display apparatus having a light emitting diode, in which link wirings for transmitting data voltages is formed within a display region AA.

Meanwhile, for convenience of explanation, in this exemplary embodiment, an organic light emitting display apparatus is described as an example of the display apparatus 10.

Referring to FIGS. 1 to 3, the display apparatus 10 of this exemplary embodiment can include a display panel 100 and a driving circuit portion for driving the display panel 100.

The driving circuit portion can include, for example, a gate driving portion (or gate driving circuit) 210, a data driving portion (or data driving circuit) 220, and a timing control portion (or timing control circuit) 240.

The display panel 100 can include a display region AA that displays an image, and a non-display region NA arranged outside the display region AA. As an example, the non-display region NA may fully or partially surround the display region AA.

In the display region AA, a plurality of pixels P can be arranged in a matrix form along a plurality of horizontal lines (or row lines) and a plurality of vertical lines (or column lines), without being limited thereto. As an example, the plurality of pixels P can be arranged in a matrix form along directions other than the horizontal lines and the vertical lines.

Here, the plurality of pixels P can include pixels that display different colors, for example, red, green, and blue pixels that display red, green, and blue, respectively, but not limited thereto. For example, the plurality of pixels P can include a white pixel in addition to the red, green, and blue pixels. Embodiments are not limited thereto. As an example, pixels of other colors such as cyan, magenta, or yellow, etc. may be alternatively or additionally included.

In the display panel 100, various signal wirings that transmit driving signals for driving the pixels P can be formed on a substrate.

In this regard, for example, a plurality of data wirings DL that transmit data signals (or data voltages), which are image signals, can extend in the vertical direction and be connected to the pixels P of the respective vertical lines.

In addition, a gate wiring GL transmitting a gate signal (or gate voltage) can be extended along the horizontal direction and be connected to the pixels P of the corresponding horizontal line.

In this exemplary embodiment, a plurality of gate signals can be used to drive each pixel P, for example, first scan signal to fourth scan signal and an emission control signal can be used. Accordingly, a plurality of gate wirings GL respectively transmitting the plurality of gate signals can be used, for example, first scan wiring to fourth scan wiring and an emission control wiring can be used. The plurality of gate signals and gate wirings GL are described in more detail below.

As such, the plurality of pixels P can be defined by the plurality of data wirings DL and gate wirings GL intersecting each other.

Each pixel P can include a light emitting diode OD as a light emitting element, and a plurality of transistors and at least one capacitor for driving the light emitting diode OD.

Meanwhile, in this exemplary embodiment, for convenience of explanation, an 8T1C structure in which the pixel P is provided with eight transistors T1 to T7 and DT and one capacitor Cst as illustrated in FIG. 2 is taken as an example. Embodiments are not limited thereto. As an example, a 2T1C structure, a 3T1C structure, a 4T2C structure etc. could be also employed.

Referring to FIG. 2, the pixel P can include a plurality of switching transistors i.e., first transistor T1 to seventh transistor T7, a driving transistor DT, a storage capacitor Cst, and the light emitting diode OD.

Each of the first to seventh transistors T1 to T7 and the driving transistor DT can include a first electrode, a second electrode, and a gate electrode. One of the first electrode and the second electrode can be a source electrode, and the other of the first electrode and the second electrode can be a drain electrode.

Each of the first to seventh transistors T1 to T7 and the driving transistor DT can be a P-type or N-type transistor. Meanwhile, in FIG. 2, a case in which the second, third, fourth, fifth, and sixth transistors T2, T3, T4, T5, and T6 are configured as P-type transistors, the first and seventh transistors T1 and T7 are configured as N-type transistors, and the driving transistor DT is configured as a P-type transistor, but not limited thereto.

The first transistor T1 to the seventh transistor T7 and the driving transistor DT can include semiconductors of the same material or may include semiconductors of different materials. In this regard, for example, some of the first transistor T1 to the seventh transistor T7 and the driving transistor DT can have one semiconductor layer among a polycrystalline silicon layer, an oxide semiconductor layer, an amorphous silicon layer, a compound semiconductor layer, an organic semiconductor layer, etc., and the other of the first transistor T1 to the seventh transistor T7 and the driving transistor DT can have another semiconductor layer among a polycrystalline silicon layer, an oxide semiconductor layer, an amorphous silicon layer, a compound semiconductor layer, an organic semiconductor layer, etc., without being limited thereto.

Meanwhile, since an oxide semiconductor has excellent off-current characteristics and thus can have characteristics suitable for a switching transistor, at least one of the first transistor T1 to the seventh transistor T7 can have an oxide semiconductor layer. In addition, since polycrystalline silicon has excellent mobility, the driving transistor DT can have a polycrystalline silicon layer. In another form, the first transistor T1 to the seventh transistor T7 and the driving transistor DT can be configured.

The gate signals provided to a n-th horizontal line (more specifically, at least one of a n-th odd horizontal line and a n-th even horizontal line constituting the n-th horizontal line) of FIG. 2 can be provided from a corresponding n-th stage of the gate driving portion 210. For example, four scan signals i.e., first to fourth scan signals SC1(n) to SC4(n) and one emission control signal EM(n) can be provided. In this case, in the display region AA, first to fourth scan wirings and an emission control wiring that are connected to the n-th stage and transmit the first to fourth scan signals SC1(n) to SC4(n) and the emission control signal EM(n) to the pixel P can be arranged. Embodiments are not limited thereto. As an example, the number of gate signals and the number of emission control signals provided to a n-th horizontal line could be changed in various ways.

The first transistor T1 can function as a sampling transistor, the second transistor T2 can function as a data supply transistor, the third and fourth transistors T3 and T4 can each function as an emission control transistor, the fifth transistor T5 can function as a bias transistor, and the sixth and seventh transistors T6 and T7 can each function as an initialization transistor.

The light emitting diode OD can include an anode electrode and a cathode electrode. The anode electrode of the light emitting diode OD can be connected to a fifth node N5, and the cathode electrode of the light emitting diode OD can be applied with a low-potential driving voltage EVSS.

The driving transistor DT can include a first electrode connected to a second node N2, a second electrode connected to a third node N3, and a gate electrode connected to a first node N1. The driving transistor DT can provide a driving current (or an emission current) to the light emitting diode OD based on a voltage of the first node N1 (i.e., the voltage (e.g., data voltage Vdata) stored in the storage capacitor Cst).

The first transistor T1 can include a first electrode connected to the first node N1, a second electrode connected to the third node N3, and a gate electrode receiving the first scan signal SC1(n). The first transistor T1 can be turned on in response to the first scan signal SC1(n), and be diode-connected between the first node N1 and the third node N3, thereby sampling a threshold voltage (Vth) of the driving transistor DT and also sampling (or applying) the data voltage Vdata to the gate electrode of the driving transistor DT.

The storage capacitor Cst can be connected between the first node N1 and a fourth node N4. The storage capacitor Cst can store or maintain a high-potential driving voltage EVDD provided thereto.

The second transistor T2 can include a first electrode connected to the data wiring DL (or receiving the data voltage Vdata), a second electrode connected to the second node N2, and a gate electrode receiving the second scan signal SC2(n). The second transistor (T2) can be turned on in response to the second scan signal SC2(n) and transmit the data voltage Vdata to the second node N2.

The third transistor T3 and the fourth transistor T4 (or first and second emission control transistors) can be connected between a power wiring of the high-potential driving voltage EVDD and the light emitting diode OD and can form a current path along which the driving current generated by the driving transistor DT moves.

The third transistor T3 can include a first electrode connected to the fourth node N4 and receiving the high-potential driving voltage EVDD, a second electrode connected to the second node N2, and a gate electrode receiving the emission control signal EM(n).

The fourth transistor T4 can include a first electrode connected to the third node N3, a second electrode connected to the fifth node N5 (or the anode electrode of the light emitting diode OD), and a gate electrode receiving the emission control signal EM(n).

The third and fourth transistors T3 and T4 can be turned on in response to the emission control signal EM(n), and in this case, the driving current can be provided to the light emitting diode OD, and the light emitting diode OD can emit light with a luminance corresponding to the driving current.

The fifth transistor T5 can include a first electrode receiving a bias voltage Vobs, a second electrode connected to the second node N2, and a gate electrode receiving the third scan signal SC3(n).

The sixth transistor T6 can include a first electrode receiving an anode reset voltage Var, a second electrode connected to the fifth node N5, and a gate electrode receiving the third scan signal SC3(n).

The sixth transistor T6 can be turned on in response to the third scan signal SC3(n) before the light emitting diode OD emits light (or after the light emitting diode OD emits light), and can initialize (or reset) the anode electrode of the light emitting diode OD using the anode reset voltage Var.

The light emitting diode OD can have a parasitic capacitor formed between the anode electrode and the cathode electrode. In addition, while the light emitting diode OD emits light, the parasitic capacitor is charged so that the anode electrode of the light emitting diode OD can have a specific voltage. Therefore, by applying the anode reset voltage Var to the anode electrode of the light emitting diode OD through the sixth transistor T6, an amount of charge accumulated in the light emitting diode OD can be initialized.

In this exemplary embodiment, the gate electrodes of the fifth and sixth transistors T5 and T6 are configured to receive the third scan signal SC3(n) in common. However, it is not necessarily limited thereto, and the gate electrodes of the fifth and sixth transistors T5 and T6 can be configured to receive separate scan signals and be controlled independently.

The seventh transistor T7 can include a first electrode receiving an initialization voltage Vini, a second electrode connected to the first node N1, and a gate electrode receiving a fourth scan signal SC4(n).

The seventh transistor T7 can be turned on in response to the fourth scan signal SC4(n) and initialize a gate electrode of the driving transistor DT using the initialization voltage Vini. Unnecessary charges can remain in the gate electrode of the driving transistor DT due to the high-potential driving voltage EVDD applied to the storage capacitor Cst. Therefore, an amount of the remaining charges can be initialized by applying the initialization voltage Vini to the gate electrode of the driving transistor DT through the seventh transistor T7.

The 8T1C structure of the pixel P described above is an example, and the pixel P of this exemplary embodiment can be configured with a different structure.

Referring to FIG. 1 again, the gate driving portion 210 can receive a gate control signal GCS from the timing control portion 240, generate the gate signals, and sequentially apply the gate signals to the plurality of gate wirings GL. For example, the gate signals can be sequentially output in the vertical direction from the bottom to the top (or from the top to the bottom) in the drawing. Embodiments are not limited thereto. As an example, the gate signals can be output in an order other than the sequential order. As an example, gate signals of some horizontal lines may be even output simultaneously.

The gate driving portion 210 can be arranged, for example, on at least one side of the display region AA. In this exemplary embodiment, a case in which the gate driving portion 210 is configured to include first and second gate driving portions 211 and 212 arranged on both sides of the display region AA is taken as an example.

The gate driving portion 210 can be formed directly in the non-display region NA on a substrate of the display panel 100 in a form of, for example, a GIP (gate-in panel) structure, and in this case, the gate driving portion 210 can be formed in processes of forming elements of the display panel 100. As another example, the gate driving portion 210 can be configured to include at least one gate IC. As an example, the gate driving portion 210 may be connected to the display panel 110 using a tape automated bonding (TAB) method, or may be connected to bonding pads of the display panel 110 using a chip-on-glass (COG) or chip-on-panel (COP) method, or may be implemented using a chip-on-film (COF) method and connected to the display panel 110, without being limited thereto.

The gate driving portion 210 configured in the GIP structure is described with further reference to FIG. 3. In FIG. 3, for convenience of explanation, a configuration of the gate driving portion 210 that drives the n-th horizontal line configured with a n-th odd horizontal line (or a 2n−1-th horizontal line) and a n-th even horizontal line (or a 2n-th horizontal line) of the display region AA is taken as an example.

The first gate driving portion 211 of the gate driving portion 210 can include, for example, a first scan driving portion (or a first scan stage) SSC1(n), an emission driving portion (or an emission stage) SEM(n), and odd and even second scan driving portions (or odd and even second scan stages) SSC2_O(n) and SSC2_E(n).

In addition, the second gate driving portion 212 of the gate driving portion 210 can include, for example, a third scan driving portion (or a third scan stage) SSC3(n), a fourth scan driving portion (or a fourth scan stage) SSC4(n), and odd and even second scan driving portions SSC2_O(n) and SSC2_E(n).

The arrangement of the first to fourth scan driving portions SSC1(n) to SSC4(n) and the emission portion SEM(n) illustrated in FIG. 3 is an example, and they can be arranged in various combinations in the first and second gate driving portions 211 and 212. As an example, any one, two, three or four of the first to fourth scan driving portions SSC1(n) to SSC4(n) and the emission portion SEM(n) may be arranged in the first gate driving portions 211, while the others of the first to fourth scan driving portions SSC1(n) to SSC4(n) and the emission portion SEM(n) may be arranged in the second gate driving portions 212.

The first scan driving portion SSC1(n) can generate the first scan signal SC1(n) and output it to the corresponding first scan wiring. Accordingly, the pixel P_O(n) of the n-th odd horizontal line and the pixel P_E(n) of the n-th even horizontal line can be commonly applied with the first scan signal SC1(n).

The odd second scan driving portion SSC2_O(n) can generate the odd second scan signal SC2_O(n) and output it to the corresponding odd second scan wiring, and the even second scan driving portion SSC2_E(n) can generate the even second scan signal SC2_E(n) and output it to the corresponding even second scan wiring. Accordingly, the pixel P_O(n) of the n-th odd horizontal line can be applied with the odd second scan signal SC2_O(n), and the pixel P_E(n) of the n-th even horizontal line can be applied with the even second scan signal SC2_E(n). Here, the odd second scan signal SC2_O(n) and the even second scan signal SC2_E(n) can have different timings. For example, the odd second scan signal SC2_O(n) and the even second scan signal SC2_E(n) can be respectively applied in a horizontal period (or data writing period) of the n-th odd horizontal line and a horizontal period (or data writing period) of the n-th even horizontal line. As an example, the horizontal period of the n-th even horizontal line may immediately follow the horizontal period of the n-th odd horizontal line, without being limited thereto. As an example, the horizontal period of the n-th odd horizontal line may immediately follow the horizontal period of the n-th even horizontal line. As an example, there may be an addition period interposed between the horizontal period of the n-th odd horizontal line and the horizontal period of the n-th even horizontal line, without being limited thereto.

The third scan driving portion SSC3(n) can generate the third scan signal SC3(n) and output it to the corresponding third scan wiring. Accordingly, the pixels P_O(n) and P_E(n) of the n-th odd and even horizontal lines can commonly receive the third scan signal SC3(n).

The fourth scan driving portion SSC4(n) can generate the fourth scan signal SC4(n) and output it to the corresponding fourth scan wiring. Accordingly, the pixels P_O(n) and P_E(n) of the n-th odd and even horizontal lines can commonly receive the fourth scan signal SC4(n).

The emission driving portion SEM(n) can generate the emission control signal EM(n) and output it to the corresponding emission control wiring. Accordingly, the pixels P_O(n) and P_E(n) of the n-th odd and even horizontal lines can commonly receive the emission control signal EM(n).

Referring to FIG. 1, the data driving portion 220 can receive image data Do and a data control signal DCS from the timing control portion 240. In response to the data control signal DCS, the data driving portion 220 can convert the image data Do into an analog image data i.e., the data voltage Vdata, and output it to the data wiring DL by horizontal line, without being limited thereto.

The data driving portion 220 can be configured to include at least one data IC. In this case, the data IC of the data driving portion 220 can be connected to the non-display region NA on one side of the corresponding display panel 100 while being mounted on a flexible circuit film, or can be mounted directly on the non-display region NA.

The timing control portion 240 can receive the image data Do and various timing signals, such as a vertical synchronization signal VSY, a horizontal synchronization signal HSY, a data enable signal DE, and a dot clock signal CLK, from, for example, an external host system through an interface such as an LVDS (Low Voltage Differential Signaling) interface or a TMDS (Transition Minimized Differential Signaling) interface. The timing control portion 240 can use the timing signals VSY, HSY, DE and CLK to generate the data control signal DCS and the gate control signal GCS and output them to the data driving portion 220 and the gate driving portion 210, respectively.

Meanwhile, in the display panel 100 of this exemplary embodiment, in order to implement a narrow bezel, link wirings transmitting the data voltages Vdata, more specifically, horizontal link wirings and vertical link wirings can be arranged within the display region AA. Furthermore, vertical power wirings and horizontal power wirings (or vertical voltage wirings and horizontal voltage wirings), which transmit the low-potential driving voltage EVSS to the pixels P within the display region AA, can be arranged within the display region AA.

In this regard, as an example, the horizontal link wiring and the horizontal power wiring can be formed of the same material, for example, a metal at the same layer, and the vertical link wiring and the vertical power wiring can be formed of the same material, for example, a metal at the same layer. In addition, on the substrate of the display panel 100, an insulating layer can be formed between a first metal layer which is a metal layer forming the horizontal link wiring and the horizontal power wiring, and the second metal layer which is a metal layer forming the vertical link wiring and the vertical power wiring. Embodiments are not limited thereto. As an example, the horizontal link wiring and the horizontal power wiring may be disposed on different layers, and/or the vertical link wiring and the vertical power wiring may be disposed on different layers, without being limited thereto.

In addition, when the display panel 100 is viewed in a plan view, horizontal wirings including the horizontal link wiring and the horizontal power wiring, and vertical wirings including the vertical link wiring and the vertical power wiring can form a mesh-shaped array structure within the display region AA.

Here, the horizontal link wiring and the vertical link wiring can be connected to each other through a link contact hole (or a first contact hole) formed in the insulating layer between them, and the horizontal power wiring and the vertical power wiring can be connected to each other through a voltage contact hole (or a second contact hole) formed in the insulating layer between them.

In this exemplary embodiment, within the display region AA, the voltage contact holes can be formed with a density the same as or similar to a density of the link contact holes. Accordingly, an appearance defect can be effectively improved in which in a non-driven state of the display apparatus 10, when the density of the voltage contact holes is much higher than the density of the link contact holes, a boundary between a region where the horizontal link wirings and the vertical link wirings are arranged and its surrounding region is visible.

Hereinafter, a structure for lowering the density of the voltage contact holes in the display region AA to a level of the density of the link contact holes to improve the appearance defect in which the boundary of the region where the link wirings are arranged is visible in the non-driven state is described in more detail.

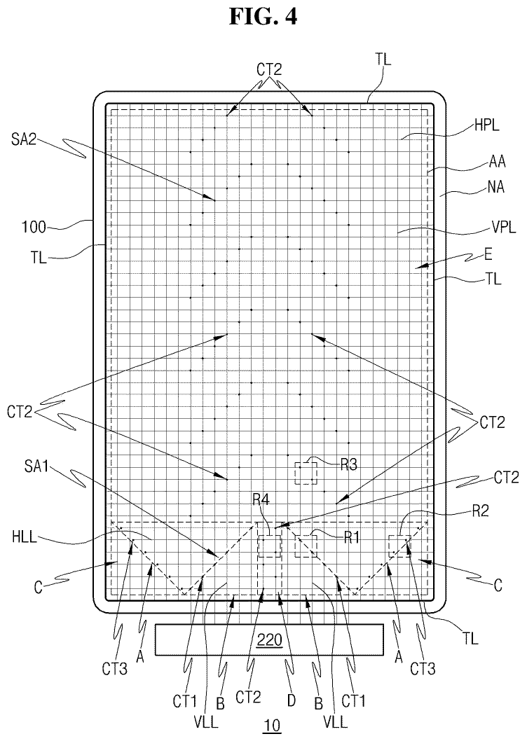

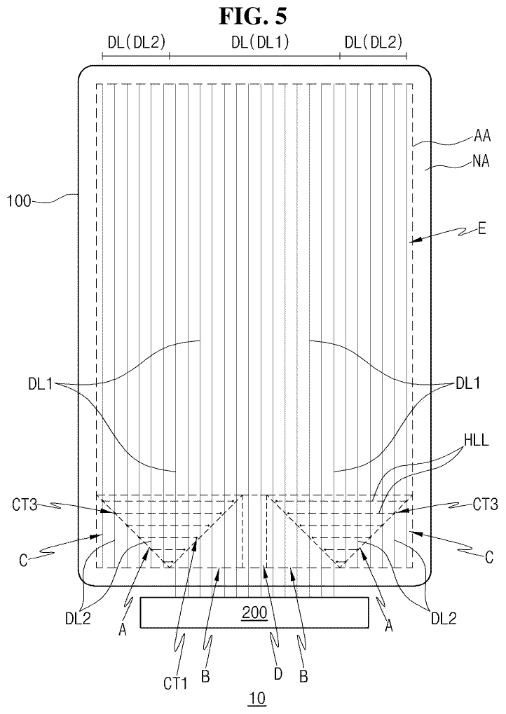

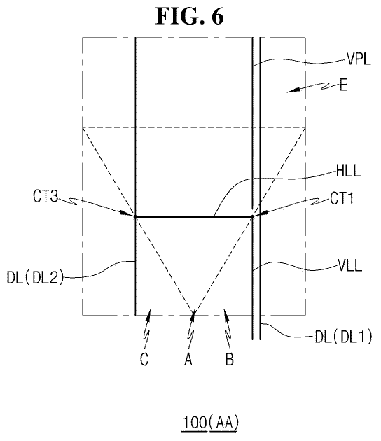

FIG. 4 is a view schematically illustrating arrangements of link wirings and power wirings formed in a display panel according to a first exemplary embodiment of the present disclosure, and FIG. 5 is a view schematically illustrating an arrangement of data wirings formed in a display panel according to a first exemplary embodiment of the present disclosure. FIG. 6 is a view schematically illustrating a connection structure of link wirings and data wirings according to a first exemplary embodiment of the present disclosure.

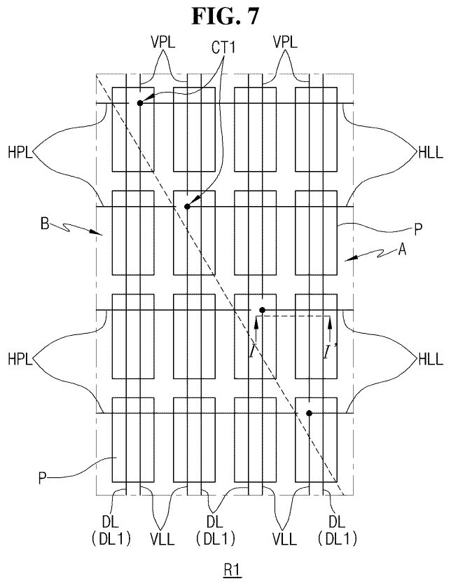

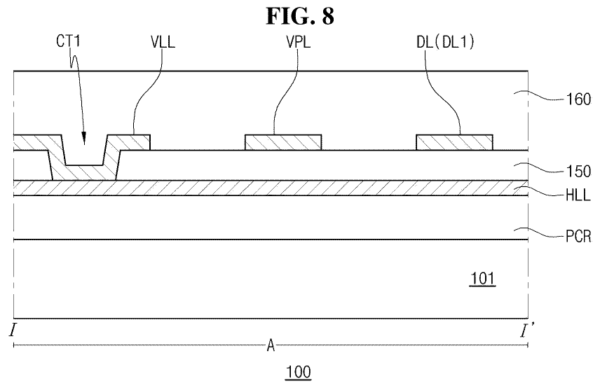

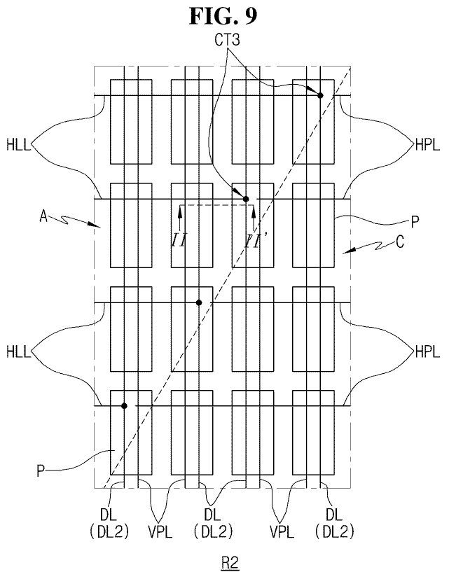

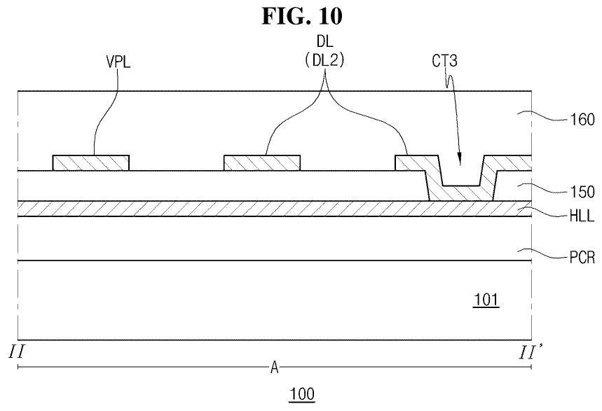

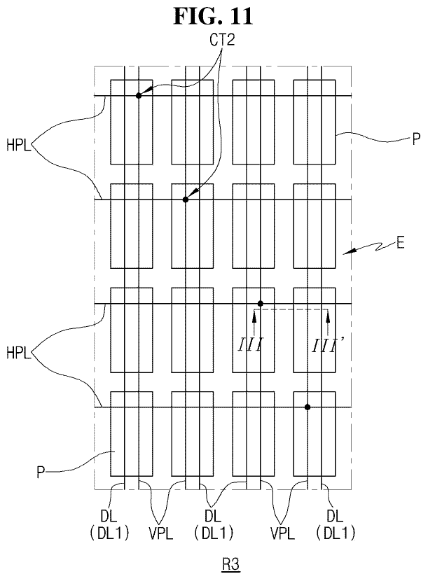

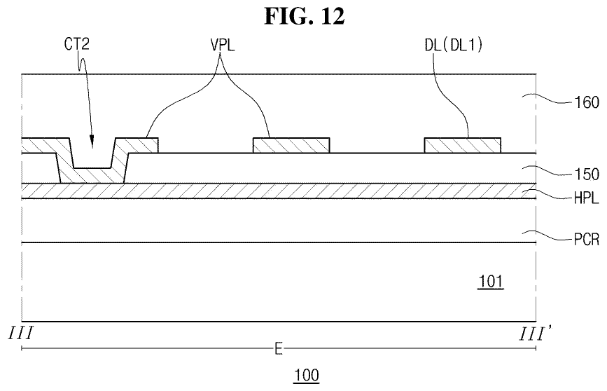

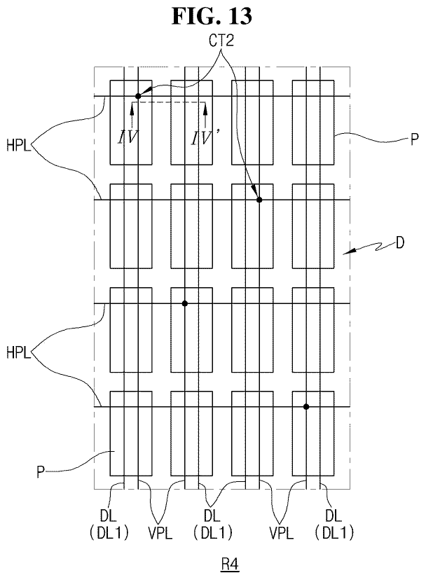

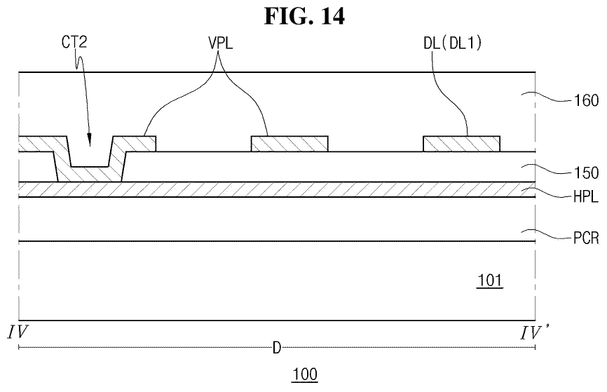

FIG. 7 is a view enlarging a region R1 of FIG. 4 according to one embodiment, and FIG. 8 is a cross-sectional view taken along a line I-I′ of FIG. 7 according to one embodiment. FIG. 9 is a view enlarging a region R2 of FIG. 4 according to one embodiment, and FIG. 10 is a cross-sectional view taken along a line II-II′ of FIG. 9 according to one embodiment. FIG. 11 is a view enlarging a region R3 of FIG. 4 according to one embodiment, and FIG. 12 is a cross-sectional view taken along a line III-III′ of FIG. 11 according to one embodiment. FIG. 13 is a view enlarging a region R4 of FIG. 4 according to one embodiment, and FIG. 14 is a cross-sectional view taken along a line IV-IV′ of FIG. 13 according to one embodiment.

Meanwhile, in this exemplary embodiment, for convenience of explanation, the link wirings VLL and HLL and the power wirings VPL and HPL, and the data wirings DL formed in the display panel 100 are separately illustrated in FIGS. 4 and 5. In addition, it is noted that in FIG. 4, for convenience of explanation, the arrangements of link contact holes CT1 and voltage contact holes CT2 (in particular, the arrangements of the voltage contact holes CT2 in a fourth region D of the display region AA) are schematically illustrated. In addition, in FIGS. 8, 10, 12, and 14, for convenience of explanation, a portion between a substrate 101, and a first metal layer (e.g., a horizontal link wiring HLL and a horizontal power wiring HPL) is simplified and illustrated as a pixel circuit layer PCR. Here, the pixel circuit layer PCR can include, for example, the transistors T1 to T7 and DT mentioned above.

Referring to FIGS. 4 to 14 along with FIGS. 1 to 3, in the display panel 100, the plurality of data wirings DL can be respectively formed along a plurality of vertical lines on which the pixels P are arranged.

In addition, in the display panel 100, a plurality of vertical wirings can be respectively formed along a plurality of vertical lines on which the pixels P are arranged, and a plurality of horizontal wirings can be respectively formed along a plurality of horizontal lines on which the pixels P are arranged.

Regarding the plurality of horizontal wirings, referring to FIGS. 8, 10, 12, and 14, for example, the plurality of horizontal wirings can include a plurality of horizontal link wirings (or first horizontal wirings) HLL which are formed at a first metal layer disposed on the pixel circuit layer PCR on a substrate 101 and transmit the data voltages Vdata into the display region AA, and a plurality of horizontal power wirings (or second horizontal wirings) HPL which are formed at the first metal layer and transmit the low-potential driving voltage EVSS into the display region AA.

For example, in a horizontal line where the horizontal link wiring HLL is arranged, the horizontal power wiring HPL separated (more specifically, physically separated) from this horizontal link wiring HLL can be arranged. In addition, in a horizontal line where the horizontal link wiring HLL is not arranged, the horizontal power wiring HPL can be arranged to substantially extend along the entirety of this horizontal line.

In addition, regarding the plurality of vertical wirings, referring to FIGS. 8, 10, 12, and 14, for example, the plurality of vertical wirings can include a plurality of vertical link wirings (or first vertical wirings) VLL which are positioned at a second metal layer different from the first metal layer and transmit the data voltages Vdata into the display region AA, and a plurality of vertical power wirings (or second vertical wirings) VPL which are positioned at the second metal layer and transmit the low-potential driving voltage EVSS into the display region. Embodiments are not limited thereto. As an example, the first metal layer and the second metal layer may be disposed under the pixel circuit layer PCR on a substrate 101, or at least one of the first metal layer and the second metal layer may be disposed inside the pixel circuit layer PCR. As an example, at least one of the first metal layer and the second metal layer may be disposed on the same layer as one metal layer inside the pixel circuit layer PCR.

For example, in a vertical line where the vertical link wiring VLL is arranged, the vertical power wiring VPL separated (more specifically, physically separated) from this vertical link wiring VLL can be arranged. In addition, in a vertical line where the vertical link wiring VLL is not arranged, the vertical power wiring VPL can be arranged to substantially extend along the entirety of this vertical line.

As such, when the display panel 100 is viewed in a plan view, as shown in FIGS. 4, 5, 7, 9, 11, and 13, the horizontal wirings configured of the horizontal link wirings HLL and the horizontal power wirings HPL, and the vertical wirings configured of the vertical link wirings VLL and the vertical power wirings VPL can intersect each other within the display region AA to form the mesh-shaped array structure.

Here, the insulating layer 150 can be formed between the first metal layer at which the horizontal link wiring HLL and the horizontal power wiring HPL are formed, and the second metal layer at which the vertical link wiring VLL and the vertical power wiring VPL are formed. Meanwhile, in this exemplary embodiment, for convenience of explanation, a case in which the first metal layer is formed below the second metal layer is taken as an example, but conversely, the first metal layer can be formed over the second metal layer. In addition, although it is illustrated that there is only one insulating layer 150 between the first metal layer and the second metal layer, embodiments are not limited thereto. As an example, there could be two or more insulating layers between the first metal layer and the second metal layer, or even one or more semiconductor layers or one or more conductive layers between the first metal layer and the second metal layer.

In addition, a passivation layer (or overcoat layer) 160 that is an insulating layer covering the vertical link wiring VLL and the vertical power wiring VPL can be formed on the second metal layer.

The horizontal link wiring HLL and the vertical link wiring VLL can be connected to each other through a corresponding link contact hole (or first contact hole) CT1 formed in the insulating layer 150 therebetween, and the horizontal power wiring HPL and the vertical power wiring VPL can be connected to each other through a corresponding voltage contact hole (or second contact hole) CT2 formed in the insulating layer 150 therebetween.

Meanwhile, the data wiring DL can be formed of the same material as and at the same layer as the vertical link wiring VLL and the vertical power wiring VPL. For example, the data wiring DL can be formed at the second metal layer. Embodiments are not limited thereto. As an example, the data wiring DL can be formed of a different material and at a different layer from the vertical link wiring VLL and the vertical power wiring VPL.

The data wiring DL can extend parallel to the vertical link wiring VLL and vertical power wiring VPL arranged in the corresponding vertical line, or the vertical power wiring VPL arranged in the corresponding vertical line. Referring to FIGS. 7, 9, 11, and 13, for example, in a vertical line where the vertical link wiring VLL is arranged, the data wiring DL can be arranged parallel to the vertical link wiring VLL and the vertical power wiring VPL that constitute the vertical wiring of this vertical line. In addition, in a vertical line where the vertical link wiring VLL is not arranged, the data wiring DL can be arranged parallel to the vertical power line VPL that constitutes the vertical line of this vertical line.

As such, in each vertical line, the data wiring DL, and the vertical wiring that extends parallel to the data wiring DL and is configured of the vertical link wiring VLL and the vertical power wiring VPL or configured of the vertical power wiring VPL can be arranged.

Referring to FIG. 5, among the plurality of data wirings DL arranged in the display region AA, some of them, for example, first data wirings DL1 arranged in a center portion of the display region AA can be electrically connected to the data driving portion 220 at one ends thereof, for example, lower ends thereof, to receive the respective data voltages Vdata, and transmit the data voltages Vdata to the pixels P of the vertical lines where the first data wirings DL1 are arranged. As an example, the center portion may occupy 30%, 50%, 60%, or 80% etc. of the display region AA, without being limited thereto. As an example, 50% or more or 50% or less among the plurality of data wirings DL may be the first data wirings DL1 arranged in a center portion, without being limited thereto.

Meanwhile, as mentioned above, in the display panel 100, the plurality of vertical link wirings VLL extending vertically from a portion adjacent to the data driving portion 220, for example, a lower portion, and the plurality of horizontal link wirings HLL extending horizontally can be formed.

The vertical link wirings VLL and the horizontal link wirings HLL can extend in the display region AA to electrically connect some of the data wirings DL different from the first data wirings DL1, for example, second data wirings DL2 to the data driving portion 220. The second data wirings DL2 can be located, for example, in portions on both sides or one side of the display region AA (i.e., left and right sides in the drawings).

In this regard, referring to FIGS. 5 and 6, one end of the vertical link wiring VLL can be electrically connected (or connected) to the data driving portion 220 to receive the corresponding data voltage Vdata. In addition, the vertical link wiring VLL can be connected to one end (or first end) of the horizontal link wiring HLL at the link contact hole CT1 located within the display region AA.

In addition, the other end (or second end) of the horizontal link wiring HLL can be connected to the corresponding second data wiring DL2 at a data contact hole (or third contact hole) CT3 which is located in the display region AA and is disposed on an opposite side of the link contact hole CT1.

The horizontal link wiring HLL can have a form in which, for example, its length increases (or lengthens or increases) as it moves away from the lower end, which is one end of the display panel 100 to which the data driving portion 220 is connected (or to which the data voltage Vdata is input), in the vertical direction, but not limited thereto.

Accordingly, the second data wiring DL2 can be electrically connected to the data driving portion 220 through the horizontal link wiring HLL and the vertical link wiring VLL connected thereto (or corresponding thereto). As such, by using the horizontal link wiring HLL and the vertical link wiring VLL arranged within the display region AA, a transmission path of the data voltage Vdata between the second data wiring DL2 and the data driving portion 220 can be formed within the display region AA.

As described above, in this exemplary embodiment, the first data wiring DL1 located at the center portion of the display region AA can be substantially connected to the data driving portion 220 to receive the corresponding data voltage Vdata, and the second data wiring DL2 located at the both side portions of the display region AA can be connected to the data driving portion 220 via the link wirings VLL and HLL arranged within the display region AA to receive the corresponding data voltage Vdata.

As such, by forming the link wirings HLL and VLL transmitting the data voltage Vdata within the display region AA, the size of the non-display region NA (e.g., the lower non-display region in the drawings) of the display panel 100 to which the data driving portion 220 is connected can be reduced, so that a narrow bezel can be effectively implemented.

In this exemplary embodiment, for convenience of explanation, the display region AA can be divided as follows. In this regard, referring to FIGS. 4 and 5, for example, a portion of the display region AA where horizontal link wirings HLL connected to the second data wirings DL2 are arranged can be referred to as a first region A. In the first region A, the vertical link wirings VLL may not be substantially arranged.

In addition, a portion of the display region AA that is located on an outer side of the first region A with respect to the horizontal direction (i.e., near the non-display region NA with respect to the horizontal direction) and has the data contact holes CT3 between the plurality of horizontal link wirings HLL and their corresponding second data wirings DL2 as a boundary with the first region A can be referred to as a third region C. In the third region C, the horizontal link wirings HLL and the vertical link wirings VLL may not be substantially arranged.

In addition, a portion of the display region AA that is located on an inner side of the first region A with respect to the horizontal direction and has the link contact holes CT1 between the plurality of horizontal link wirings HLL and their corresponding vertical link wirings VLL as a boundary with the first region A can be referred to as a second region B. In the second region B, the horizontal link wirings HLL may not be substantially arranged.

In addition, a portion of the display region AA that is located on an inner side of the third region C with respect to the horizontal direction and where the vertical link wirings VLL and the horizontal link wirings HLL are not substantially arranged can be referred to as a fourth region D. As an example, the fourth region D may be omitted depending on the design.

In addition, a portion of the display region AA that is located on an outer side (i.e., an upper side) of the first region A to the fourth region D with respect to the vertical direction and where the horizontal link wirings HLLs and the vertical link wirings VLLs are not arranged can be referred to as a fifth region E.

In the case of dividing the regions as above, in the second region B, the first data wiring DL1 crossing the second region B vertically can be arranged, so that the second region B can be applied with the data voltage Vdata through the first data wiring DL1. The boundary of the second region B with the first region A can have, for example, a sloped shape that is inclined inwardly as it goes toward the upper side of the display panel 100. As an example, the second region B can have an approximately right triangle shape (or tapered shape) whose width becomes narrower as it goes toward the upper side of the display panel 100. The second regions B can be located on both sides with the fourth region D which is a central region, and the fourth region D can be located between both second regions B.

In addition, in the third region C, the second data wiring DL2 crossing the third region C vertically can be arranged, so that the third region C can be supplied with the data voltage Vdata through the vertical link line VLL, which is arranged in the second region B, and the horizontal link line HL which is arranged in the first region A. The boundary of the third region C with the first region A can have, a sloped shape that is inclined outwardly as it goes toward the upper side of the display panel 100. As an example, the third region C can have an approximately right triangle shape (or tapered shape) whose width becomes narrower as it goes toward the upper side of the display panel 100. The third regions C can be arranged symmetrically on the left and right sides of the display region AA.

In addition, in the first region A, the first data wiring DL1 and the second data wiring DL2 crossing the first region A vertically can be arranged together. For example, with respect to a center of the first region A, the first data wirings DL1 can be arranged in a portion close to the second region B, and the second data wirings DL2 can be arranged in a portion close to the third region C. The first region A can be interposed between the second and third regions B and C, and can have, for example, an approximately isosceles triangle shape (or an inverse tapered shape) whose width becomes wider as it goes toward the upper side of the display panel 100. The first regions A can be arranged symmetrically to the left and right sides of the display region AA. Embodiments are not limited thereto. As an example, as long as the second data wiring DL2 is connected to the horizontal link wiring HLL, which is connected to the vertical link line VLL, which is connected to the data driving portion 220, the regions A, B, C, D could be varied in various ways.

In addition, in the fourth region D, which is a central region located between the second regions B on the left and right, the first data wiring DL1 crossing the fourth region D vertically can be arranged, so that the fourth region D can be applied with the data voltage Vdata through the first data wiring DL1. The boundary of the fourth region D with the second region B can have, for example, a shape that extends vertically toward the upper side of the display panel 100. As an example, the fourth region D can have an approximately rectangular shape with a constant width as it goes upward, without being limited thereto.

In addition, in the fifth region E located on the upper side of the first region A to the fourth region D, the first and second data wirings DL1 and DL2 crossing the fifth region E vertically can be arranged, so that the firth region E can be applied with the data voltages Vdata through the first and second data wirings DL1 and DL2. In this regard, a portion of the fifth region E positioned corresponding to the second region B and the fourth region D (i.e., positioned on the upper side of the second region B and the fourth region D) can receive the data voltage Vdata through the first data wiring DL1, and a portion of the fifth region E positioned corresponding to the third region C (i.e., positioned on the upper side of the third region C) can receive the data voltage Vdata through the second data wiring DL2.

Meanwhile, in the first region A to the fifth region E of the display region AA arranged as above, the horizontal power wirings HPL and/or the vertical power wirings VPL can be arranged, and the low-potential driving voltage EVSS transmitted through the horizontal power wirings HPL and/or the vertical power wirings VPL can be provided to the pixels P within the first region A to the fifth region E.

In this regard, for example, in the fifth region E where the horizontal link wiring HLL and the vertical link wiring VLL are not arranged, the horizontal power wiring HPL and the vertical power wiring VLL can be arranged.

Similarly, in the fourth region D where the horizontal link wiring HLL and the vertical link wiring VLL are not arranged, the horizontal power wiring HPL and the vertical power wiring VLL can be arranged.

In addition, in the first region A where the horizontal link wiring HLL is arranged and the vertical link wiring VLL is not arranged, the vertical power wiring VPL can be arranged. The vertical power wiring VPL arranged in the first region A can extend into the fifth region E. Meanwhile, along the boundary between the first and second regions A and B, the vertical power wiring VPL of the first region A can be separated from the vertical link wiring VLL of the second region B corresponding thereto (i.e., arranged on the same vertical line). As an example, the vertical power wiring VPL of the first region A and the vertical link wiring VLL of the second region B corresponding thereto may be arranged on the same vertical line, while separated from each other in the vertical direction, such that the vertical power wiring VPL is not disposed in the second region B, and the vertical link wiring VLL is not disposed in the first region A.

In addition, in the second region B where the vertical link wiring VLL is arranged and the horizontal link wiring HLL is not arranged, the horizontal power wiring HPL can be arranged. The horizontal power wiring HPL arranged in the second region B can extend into the fourth region D. Meanwhile, along the boundary between the first and second regions A and B, the horizontal power wiring HPL of the second region B can be separated from the horizontal link wiring HLL of the first region A corresponding thereto (i.e., arranged on the same horizontal line). As an example, the horizontal power wiring HPL of the second region B and the horizontal link wiring HLL of the first region A corresponding thereto may be arranged on the same horizontal line, while separated from each other in the horizontal direction, such that the horizontal power wiring HPL is not disposed in the region A and the horizontal link wiring HLL is not disposed in the second region B.

In addition, in the third region C where the vertical link wiring VLL and the horizontal link wiring HLL are not arranged, the vertical power wiring VPL and the horizontal power wiring HPL can be arranged. The vertical power wiring VPL arranged in the third region C can extend into the first and fifth regions A and E. Meanwhile, along the boundary between the first and third areas A and C, the horizontal power wiring HPL of the third region C can be separated from the horizontal link wiring HLL of the first region A corresponding thereto (i.e., arranged on the same horizontal line). As an example, the horizontal power wiring HPL of the third region C can be separated from the horizontal link wiring HLL of the first region A corresponding thereto in a horizontal direction.

As above, the horizontal link wirings HLL and the vertical link wirings VLL arranged in the display region AA can be connected through the link contact holes CT1 arranged along the boundary between the first and second regions A and B.

In this regard, the link contact holes CT1 can be arranged along the boundary between the first and second regions A and B, so that the link contact holes CT1 can have a sloped shape that is inclined inwardly as it goes upward. As an example, the link contact holes CT1 can form a sloped array structure that is inclined inwardly.

In the inwardly sloped array structure along the boundary between the first and second regions A and B, one link contact hole CT1 can be formed for each horizontal link wiring HLL i.e., for each horizontal line.

As such, since one link contact hole CT1 is formed per horizontal line at the boundary between the first and second regions A and B, the density of the link contact hole CT1 is very low. In addition, there is substantially no contact hole in the insulating layer 150 between the first metal layer and the second metal layer within the first region A and within the second region B.

Therefore, in the non-driven state of the display apparatus 10, the boundary between the first and second regions A and B adjacent to each other is substantially not recognized.

In addition, the horizontal link wirings HLL and the second data wirings DL2 arranged in the display region AA can be connected through the data contact holes CT3 arranged along the boundary between the first and third regions A and C.

In this regard, the data contact holes CT3 can be arranged along the boundary between the first and third regions A and C, so that the data contact holes CT3 can have a sloped shape that is inclined outwardly as it goes upward. As an example, the data contact holes CT3 can form a sloped array structure that is inclined outwardly.

In the outwardly sloped array structure along the boundary between the first and third regions A and C, one data contact hole CT3 can be formed for each horizontal link wiring HLL i.e., for each horizontal line.

As such, since one data contact hole CT3 is formed per horizontal line at the boundary between the first and third regions A and C, the density of the data contact hole CT3 is very low. In addition, there is substantially no contact hole in the insulating layer 150 between the first metal layer and the second metal layer within the first region A and within the third region C.

Therefore, in the non-driven state of the display apparatus 10, the boundary between the first and third regions A and C adjacent to each other is substantially not recognized.

Meanwhile, in this exemplary embodiment, the horizontal power wirings HPL and the vertical power wirings VPL arranged in the display region AA can be connected through the voltage contact holes CT2 formed in, for example, the fourth and fifth regions D and E. As an example, the horizontal power wiring HPL and the vertical power wiring VPL arranged in the display region AA can be substantially connected to each other in the fourth and fifth regions D and E.

In addition, the horizontal power wirings HPL and the vertical power wirings VPL arranged in the display region AA can be connected to a transmission wiring TL formed along the non-display region NA.

In this regard, the low-potential driving voltage EVSS supplied from a power circuit outside the display panel 100 can be applied to the transmission wiring TL formed in the non-display region NA, and the transmission wiring TL can provide the low-potential driving voltage EVSS to the horizontal power wirings HPL and the vertical power wirings VPL arranged within the display region AA.

As such, the low-potential driving voltage EVSS can be provided to the pixels P arranged within the display region AA through the horizontal power wirings HPL and the vertical power wirings VPL arranged within the display region AA.

In addition, the horizontal power wirings HPL and the vertical power wirings VPL can be connected to each other through the voltage contact holes CT2 arranged in the fourth and fifth regions D and E of the display region AA, so that a substantially uniform low-potential driving voltage EVSS can be transmitted in the horizontal and vertical directions within the display region AA.

As described above, the voltage contact hole CT2 connecting the horizontal power wiring HPL and the vertical power wiring VPL in the fourth and fifth regions D and E can be formed at a very low density, substantially the same as or similar to the density of the link contact hole CT1 (or the density of the data contact hole CT3).

In this regard, in the fourth region D, which is the central region located between the left and right second regions B where the vertical link wirings VLL are arranged, for example, one (or two) voltage contact hole CT2 can be formed per horizontal line, without being limited thereto. Meanwhile, in this exemplary embodiment, as shown in FIGS. 4 and 13, a case in which one voltage contact hole CT2 is formed per horizontal line in the fourth region D is taken as an example.

In this case, within the fourth region D, the voltage contact holes CT2 can be arranged to be substantially uniformly (or evenly) distributed. For example, as shown in FIGS. 4 and 13, within the fourth region D, when one voltage contact hole CT2 is formed per horizontal line, the voltage contact holes CT2 can be arrayed diagonally from one side (for example, the left side) boundary of the fourth region D to the other side (for example, the right side) boundary of the fourth region D, and this diagonal array can be repeated along the vertical direction.

As such, since one (or two) voltage contact hole CT2 are formed per horizontal line in the fourth region D, the density of the voltage contact hole CT2 within the fourth region D is very low. That is, the density of the voltage contact hole CT2 of the fourth region D is very low, similar to the density of the link contact hole CT1 arranged at the boundary between the first and second regions A and B.

In addition, in the second region B adjacent to the fourth region D, there is substantially no contact hole in the insulating layer 150 between the first metal layer and the second metal layer.

Therefore, in the non-driven state of the display apparatus 10, the boundary between the second and fourth regions B and D adjacent to each other is substantially not recognized.

Meanwhile, in the fifth region E located above the left and right first regions A where the horizontal link wirings HLL are arranged, for example, the voltage contact holes CT2 can be formed in a second sloped array form SA2 that is substantially the same as a first sloped array form SA1 that is a sloped array form (or sloped array structure) of the link contact holes CT1 formed along the boundary between the first and second regions A and B.

In this regard, for example, regarding the fifth region E, in a left portion with respect to a center of the fifth region E, the voltage contact holes CT2 can be formed in the second sloped array form SA2 that is substantially the same as the first sloped array form SA1 of the link contact holes CT1 along the boundary between the left first and second regions A and B corresponding to the left portion of the fifth region E. As an example, the left portion may correspond to the second region B in the vertical direction, without being limited thereto. As an example, a width of the left portion may be equal to, greater than or smaller than that if the second region B. As an example, the center of the fifth region E may correspond to the fourth region D in the vertical direction, without being limited thereto. Likewise, regarding the fifth region E, in a right portion with respect to a center of the fifth region E, the voltage contact holes CT2 can be formed in the second sloped array form SA2 that is substantially the same as the first sloped array form SA1 of the link contact holes CT1 along the boundary between the right first and second regions A and B corresponding to the right portion of the fifth region E.

As such, the voltage contact holes CT2 of the fifth region E can be arranged in a sloped direction substantially parallel to the link contact holes CT1 while being positioned on the same vertical lines as the link contact holes CT1, so that the sloped array form SA2 of the voltage contact holes CT2 can be the same as the sloped array form SA1 of the link contact holes CT1 positioned correspondingly below it.

As an example, the sloped array form SA2 of the voltage contact holes CT2 of the fifth region E can be configured to have substantially the same length (or range) in the horizontal direction as the sloped array form SA1 of the link contact holes CT1.

Meanwhile, as illustrated in FIG. 4, the vertical length of the fifth region E can be formed longer than the vertical lengths of the first and second regions A and B, and in this case, the second sloped array form SA2 can be repeated in the upper direction in the fifth region E. Embodiments are not limited thereto. As an example, the second sloped array form SA2 can be repeated in the horizontal direction in the fifth region E. As an example, the second sloped array form SA2 can be repeated in the upper direction in the fifth region E for an integral multiple times, without being limited thereto.

In this case, as an example, in each of the left and right portions of the fifth region E, one voltage contact hole CT2 can be formed per horizontal line.

As above, in each of the left and right portions of the fifth region E, the voltage contact holes CT2 arrayed in the same form as the link contact holes CT1 which are located below the voltage contact holes CT2 and arranged along the boundary between the first and second regions A and B can formed in each of the left and right portions of the fifth region E. Accordingly, the density of the voltage contact holes CT2 in the fifth region D can have a very low level that is substantially the same as the density of the link contact holes CT1 arranged along the boundary between the first and second regions A and B.

In addition, in the first region A adjacent to the fifth region E, there is substantially no contact hole in the insulating layer 150 between the first metal layer and the second metal layer.

Therefore, in the non-driven state of the display apparatus 10, the boundary between the adjacent first and fifth regions A and E is substantially not recognized.

As described above, in this exemplary embodiment, for the first and second regions A and B, i.e., link wiring regions A and B which are portions of the display region AA where the horizontal link wirings HLL and the vertical link wirings VLL are arranged, the voltage contact holes CT2 are not substantially formed in the third region C which is on the outer side of and adjacent to the link wiring regions A and B, one (or two) voltage contact hole CT2 is formed per horizontal line in the fourth region D which is a central region on the inner side of and adjacent to the link wiring regions A and B, and the voltage contact holes CT2 arranged in the same array form as the link contact holes CT1 are formed in the fifth region E which is on the upper side of and adjacent to the link wiring regions A and B.

As such, the density of the voltage contact holes CT2 in the regions C, D and E horizontally and vertically adjacent to the link wiring regions A and B is similar to the density of the link contact holes CT1 arranged along the boundary between the first and second regions A and B, or is substantially 0 (i.e., in the third region C), so that the density of the voltage contact holes CT2 is very low.

Therefore, in the non-driven state of the display apparatus 10, the boundary between the link wiring regions A and B and its adjacent regions C, D and E is substantially not visible. Accordingly, an appearance defect in which when high-density voltage contact holes CT2 are formed in the adjacent regions C, D and E, the boundary between the link wiring regions A and B and the adjacent regions C, D and E is visible can be reduced, prevented or removed.

Furthermore, in this exemplary embodiment, in the fifth region E located on the upper side of the link wiring regions A and B, the voltage contact holes CT2 arranged in the same array form as the link contact holes CT1 formed in the link wiring regions A and B are formed. As such, since the contact holes CT1 and CT2 with very low density are repeatedly formed in the same array form along the vertical direction, possibility of the contact holes CT1 and CT2 being visible can be further reduced.

### Second Exemplary Embodiment

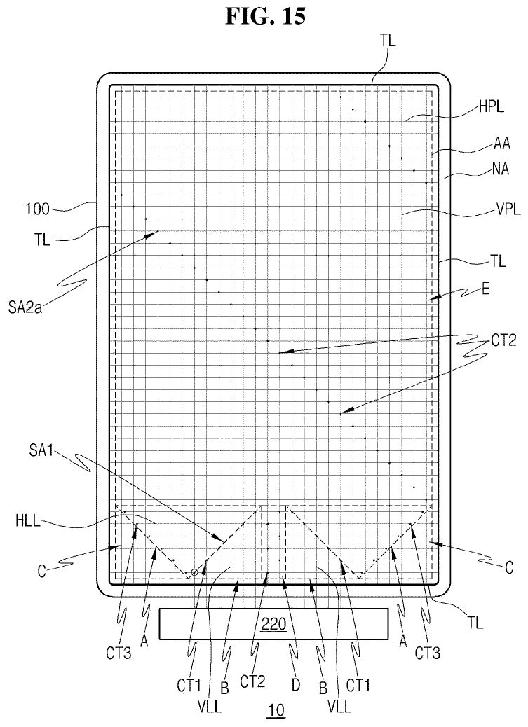

FIG. 15 is a view schematically illustrating arrangements of link wirings and power wirings formed in a display panel according to a second exemplary embodiment of the present disclosure.

In the following description, specific explanations of configurations identical to or similar to those of the first exemplary embodiment described above can be omitted.

Referring to FIG. 15, the voltage contact holes CT2 formed in the fifth region E of the display region AA of this exemplary embodiment can have a second sloped array form SA2a as a sloped array form, and this second sloped array form SA2a can be different from the first sloped array form SA1 of the link contact holes CT1 formed at the boundary between the first and second regions A and B.

In this regard, for example, in the fifth region E, the voltage contact holes CT2 can be formed one by one per horizontal line, and can be arranged from one end of the horizontal direction, for example, the right end, to the other end, for example, the left end, as it goes upward, so that the voltage contact holes CT2 can have the array form SA2a inclined to the left. As another example, the voltage contact holes CT2 of the fifth region E can be arranged inclined to the right.

In addition, as illustrated in FIG. 15, the vertical length of the fifth region E can be formed longer than the vertical lengths of the first and second regions A and B, and in this case, the second sloped array form SA2a can be repeated in the upper direction in the fifth region E.

As such, in this exemplary embodiment, the second sloped array form SA2a of the voltage contact holes CT2 of the fifth region E can have a wider length (or range) in the horizontal direction than the first slope array form SA1 of the link contact holes CT1.

As such, since the voltage contact holes CT2 in the fifth region E has the array form SA2a in which one voltage contact hole CT2 is substantially formed per horizontal line, number and density of the voltage contact holes CT2 in the fifth region E can be lowered compared to the first exemplary embodiment.

Meanwhile, the array form of the voltage contact holes CT2 in the third and fourth regions C and D of this exemplary embodiment can be configured in the same manner as the array form of the voltage contact holes CT2 in the third and fourth regions C and D of the first exemplary embodiment described above.

Therefore, in this exemplary embodiment, in the non-driven state of the display apparatus 10, the boundary between the link wiring regions A and B and its adjacent regions C, D and E is substantially not visible, so that the occurrence of appearance defect due to the boundary between the link wiring regions A and B and the adjacent regions C, D and E being visible can be improved.

### Third Exemplary Embodiment

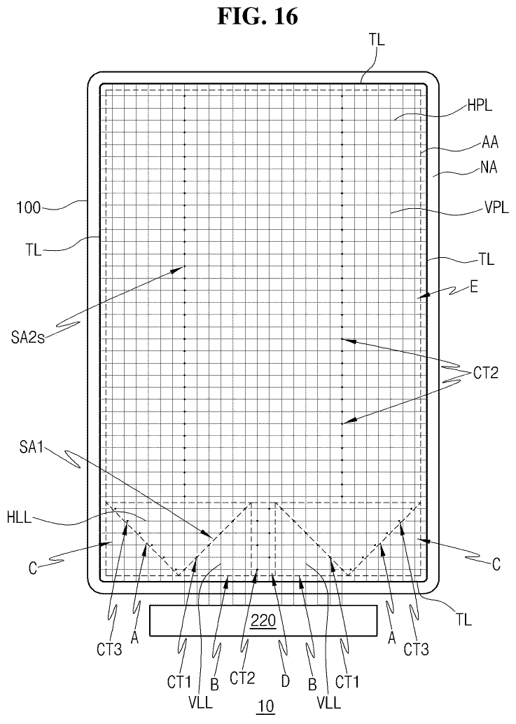

FIG. 16 is a view schematically illustrating arrangements of link wirings and power wirings formed in a display panel according to a third exemplary embodiment of the present disclosure.

In the following description, specific explanations of configurations identical to or similar to those of the first and second exemplary embodiments described above can be omitted.

Referring to FIG. 16, the voltage contact holes CT2 formed in the fifth region E of the display region AA of this exemplary embodiment can have a vertical array form SA2s arranged in a straight line along the vertical direction, unlike the sloped array form of the first and second exemplary embodiments described above.

In this regard, for example, in each of the left and right portions of the fifth region E, the voltage contact holes CT2 can be formed one by one per horizontal line and be positioned along substantially the same vertical line, thereby having the vertical array form SA2s.

In addition, as an example, the vertical array form SA2s in each of the left and right portions of the fifth region E can be substantially configured at a center of each of the left portion and the center of the right portion. Embodiments are not limited thereto. As an example, the vertical array form SA2s in each of the left and right portions of the fifth region E can be biased from the center of each of the left portion and the center of the right portion. As an example, the vertical array form SA2s in each of the left and right portions of the fifth region E can be symmetric with each other or may be asymmetric with each other.

As such, in this exemplary embodiment, the voltage contact holes CT2 of the fifth region E can be formed in the vertical array form SA2s in the inner region of each of the left and right portions.

Since the vertical array form SA2s is provided in this way, number and density of the voltage contact holes CT2 in the fifth region E can be substantially the same as those of the first exemplary embodiment.

Meanwhile, the array form of the voltage contact holes CT2 in the third and fourth regions C and D of this exemplary embodiment can be configured in the same manner as the array form of the voltage contact holes CT2 in the third and fourth regions C and D of the first and second exemplary embodiments described above.

Therefore, in this exemplary embodiment, in the non-driven state of the display apparatus 10, the boundary between the link wiring regions A and B and its adjacent regions C, D and E is substantially not visible, so that the occurrence of appearance defect due to the boundary between the link wiring regions A and B and the adjacent regions C, D and E being visible can be improved.

### Fourth Exemplary Embodiment

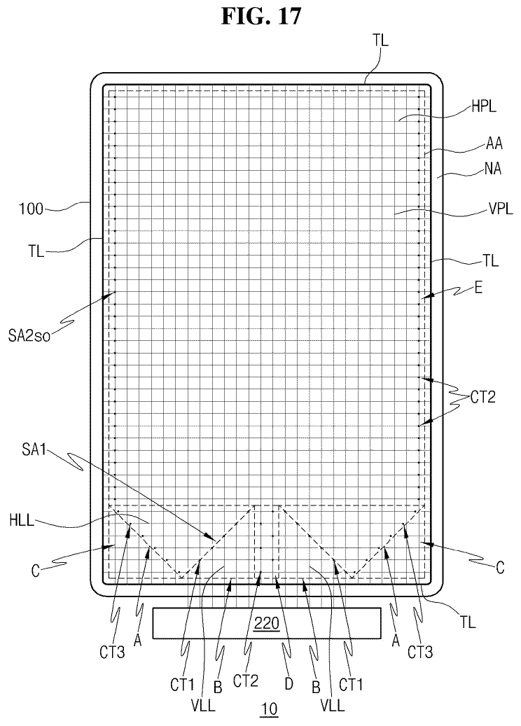

FIG. 17 is a view schematically illustrating arrangements of link wirings and power wirings formed in a display panel according to a fourth exemplary embodiment of the present disclosure.

In the following description, specific explanations of configurations identical to or similar to those of the first to third exemplary embodiments described above can be omitted or briefly given.

Referring to FIG. 17, the voltage contact holes CT2 formed in the fifth region E of the display region AA of this exemplary embodiment can have a vertical array form SA2so arranged in a straight line along the vertical direction, similar to the vertical array form of the third exemplary embodiment described above.

In this regard, for example, in each of the left and right portions of the fifth region E, the voltage contact holes CT2 can be formed one by one per horizontal line and be positioned along substantially the same vertical line, thereby having the vertical array form SA2so.

Meanwhile, the position of the vertical array form SA2so in the fifth region E of this exemplary embodiment can be configured at each of the outermost side of the left portion and the outermost side of the right portion, respectively, unlike the third exemplary embodiment.

As such, in this exemplary embodiment, the voltage contact holes CT2 of the fifth region E can be formed in the vertical array form SA2so at the outermost side of each of the left portion and the right portion.

Since the vertical array form SA2so is provided in this way, number and density of the voltage contact holes CT2 in the fifth region E can be substantially the same as those in the first exemplary embodiment.

Meanwhile, the array form of the voltage contact holes CT2 in the third and fourth regions C and D of this exemplary embodiment can be configured in the same manner as the array form of the voltage contact holes CT2 in the third and fourth regions C and D of the first and second exemplary embodiments described above.

Therefore, in this exemplary embodiment, in the non-driven state of the display apparatus 10, the boundary between the link wiring regions A and B and its adjacent regions C, D and E is substantially not visible, so that the occurrence of appearance defect due to the boundary between the link wiring regions A and B and the adjacent regions C, D and E being visible can be improved.

As described above, according to the exemplary embodiments of the present disclosure, for the first and second regions, i.e., link wiring regions which are portions of the display region where the horizontal link wirings and the vertical link wirings are arranged, the voltage contact holes are not substantially formed in the third region which is on the outer side of and adjacent to the link wiring regions, one (or two) voltage contact hole is formed per horizontal line in the fourth region which is a central region on the inner side of and adjacent to the link wiring regions, and the voltage contact holes arranged in the same array form as the link contact holes are formed in the fifth region which is on the upper side of and adjacent to the link wiring regions.

As such, the density of the voltage contact holes in the regions horizontally and vertically adjacent to the link wiring regions is similar to or lower than the density of the link contact holes arranged along the boundary between the first and second regions, so that the density of the voltage contact holes is very low.

Therefore, in the non-driven state of the display apparatus, the boundary between the link wiring regions and its adjacent regions is substantially not visible. Accordingly, an appearance defect in which when high-density voltage contact holes are formed in the adjacent regions, the boundary between the link wiring regions and the adjacent regions is visible can be reduced, prevented or removed.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display apparatus, comprising:
a display panel in which a display region is defined and includes pixels arranged along a plurality of vertical lines and a plurality of horizontal lines, the display region including a first region, a second region, and a third region respectively located on inner and outer sides, in a horizontal direction, of the first region, and a fifth region located on an upper side, in a vertical direction, of the first region;
a data wiring extending along a vertical line from the plurality of vertical lines of the display region;
a horizontal link wiring extending along a horizontal line from the plurality of horizontal lines of the first region, and connected to the data wiring arranged in the third region at a third contact hole that is arranged along a sloped boundary between the first region and the third region;
a vertical link wiring extending along a vertical line from the plurality of vertical lines of the second region, and connected to the horizontal link wiring at a first contact hole that is arranged along a sloped boundary between the first region and the second region;
a horizontal power wiring extending along the horizontal line of the second region, the third region, and the fifth region and transmitting a low-potential driving voltage; and
a vertical power wiring extending along the vertical line of the first region, the third region, and the fifth region and transmitting the low-potential driving voltage,
wherein a second contact hole is in the fifth region and connects the horizontal power wiring and the vertical power wiring, and
wherein the second contact hole is arranged in a sloped array form or a vertical array form in the fifth region.

2. The display apparatus of claim 1, wherein the sloped array form of the second contact hole of the fifth region is a same as a sloped array form of the first contact hole along the sloped boundary between the first region and the second region.

3. The display apparatus of claim 2, wherein the sloped array form of the second contact hole of the fifth region is parallel to the sloped array form of the first contact hole along the sloped boundary between the first region and the second region, while being positioned on the same vertical lines as the sloped array form of the first contact hole along the sloped boundary between the first region and the second region.

4. The display apparatus of claim 1, wherein the sloped array form of the second contact hole of the fifth region is different from a sloped array form of the first contact hole along the sloped boundary between the first region and the second region.

5. The display apparatus of claim 1, wherein the vertical array form of the second contact hole of the fifth region is at a center of each of a left portion and a right portion of the fifth region or at an outermost side of each of the left portion and the right portion of the fifth region.

6. The display apparatus of claim 2, wherein in the sloped array form of the second contact hole of the fifth region, the second contact hole is arranged one by one per horizontal line from the plurality of horizontal lines.

7. The display apparatus of claim 5, wherein in the vertical array form of the second contact hole of the fifth region, the second contact hole is arranged one by one per horizontal line from the plurality of horizontal lines.

8. The display apparatus of claim 1, wherein the display region further includes a fourth region on an inner side, in the horizontal direction, of the second region,
wherein the second contact hole is in the fourth region and connects the horizontal power wiring and the vertical power wiring, and
wherein one or two second contact holes are arranged per horizontal line from the plurality of horizontal lines in the fourth region.

9. The display apparatus of claim 1, wherein the second contact hole connecting the horizontal power wiring and the vertical power wiring is not in the third region.

10. The display apparatus of claim 1, wherein the display panel includes:
a first metal layer at which the horizontal link wiring and the horizontal power wiring are formed;
a second metal layer at which the vertical link wiring, the vertical power wiring, and the data wiring are formed; and
an insulating layer between the first metal layer and the second metal layer, and including the first, second, and third contact holes.

11. The display apparatus of claim 10, wherein the first metal layer and the second metal layer are on a pixel circuit layer that includes transistors.

12. The display apparatus of claim 1, further comprising:
a transmission wiring located in a non-display region that is outside the display region, the low-potential driving voltage applied to the transmission wiring,
wherein the vertical link wiring and/or the horizontal link wiring are connected to the transmission wiring.

13. The display apparatus of claim 1, wherein a pixel from the pixels includes a light emitting diode that receives the low-potential driving voltage.

14. The display apparatus of claim 1, wherein in a horizontal line from the plurality of horizontal lines where a horizontal link wiring is arranged, a horizontal power wiring separated from said horizontal link wiring in a horizontal direction is arranged, and in a horizontal line from the plurality of horizontal lines where a horizontal link wiring is not arranged, the horizontal power wiring extends along an entirety of said horizontal line.

15. The display apparatus of claim 1, further comprising:
a data driving portion that supplies a data voltage,
wherein data wirings arranged in the second region are electrically connected to the data driving portion directly, and
wherein data wirings arranged in the third region are electrically connected to the data driving portion through horizontal link wirings arranged in the first region and vertical link wirings arranged in the second region.

16. The display apparatus of claim 1, wherein each of the second region and the third region has a right triangle shape whose width becomes narrower as it goes toward the upper side, and the first region has an isosceles triangle shape whose width becomes wider as it goes toward the upper side.

17. The display apparatus of claim 1, wherein a vertical power wiring in the first region and a vertical link wiring in the second region arranged in a same vertical line from the plurality of vertical lines are separated from each other in a vertical direction, and
wherein a horizontal power wiring in the second region and a horizontal link wiring in the first region arranged in a same horizontal line from the plurality of horizontal lines are separated from each other in a horizontal direction.

18. A display apparatus, comprising:
a display panel in which a display region is defined and includes pixels arranged along a plurality of vertical lines and a plurality of horizontal lines, the display region including a first region, a second region located on an inner side, in a horizontal direction, of the first region, and a fifth region located on an upper side, in a vertical direction, of the first region;
a data wiring extending along a vertical line from the plurality of vertical lines of the display region;
a horizontal link wiring extending along a horizontal line from the plurality of horizontal lines of the first region;
a vertical link wiring extending along a vertical line from the plurality of vertical lines of the second region, and connected to the horizontal link wiring at a first contact hole that is arranged along a boundary between the first region and the second region; and
a horizontal power wiring and a vertical power wiring respectively extending along a horizontal line from the plurality of horizontal lines and a vertical line from the plurality of vertical lines of the fifth region, and transmitting a low-potential driving voltage,
wherein a second contact hole connecting the horizontal power wiring and the vertical power wiring in the fifth region is arranged in a sloped array form or a vertical array form.

19. The display apparatus of claim 18, wherein the display panel includes:
a first metal layer at which the horizontal link wiring and the horizontal power wiring are formed;
a second metal layer at which the vertical link wiring, the vertical power wiring, and the data wiring are formed; and
an insulating layer between the first metal layer and the second metal layer, the insulating layer including the first contact hole and the second contact hole.

20. The display apparatus of claim 18, wherein the sloped array form of the second contact hole of the fifth region has a length in the horizontal direction equal to or greater than that of a sloped array form of the first contact hole along the boundary between the first region and the second region, and
wherein in the sloped array form of the second contact hole of the fifth region, the second contact hole is arranged one by one per horizontal line from the plurality of horizontal lines.

21. The display apparatus of claim 18, wherein the vertical array form of the second contact hole of the fifth region is configured at a center of each of a left portion and a right portion of the fifth region or at an outermost side of each of the left portion and the right portion of the fifth region, and
wherein in the vertical array form of the second contact hole of the fifth region, the second contact hole is arranged one by one per horizontal line from the plurality of horizontal lines.

22. The display apparatus of claim 18, wherein the display region further includes a third region located on an outer side, in the horizontal direction, of the first region, and a fourth region located on an inner side, in the horizontal direction, of the second region,
wherein the second contact hole is in the fourth region to connect the horizontal power wiring and the vertical power wiring, and
wherein one or two second contact holes are arranged per horizontal line from the plurality of horizontal lines within the fourth region.

23. The display apparatus of claim 22, wherein the second contact hole connecting the horizontal power wiring and the vertical power wiring is not formed in the third region.

24. The display apparatus of claim 18, further comprising:
a transmission wiring in a non-display region outside the display region, the low-potential driving voltage applied to the transmission wiring,
wherein the vertical link wiring and/or the horizontal link wiring are connected to the transmission wiring.

25. The display apparatus of claim 18, wherein a pixel from the pixels includes a light emitting diode that receives the low-potential driving voltage.
